(19) United States
(12) Patent Application Publication
(10) Pub. No.: US 2005/0030564 A1
(43) Pub. Date: Feb. 10, 2005

(54) Output image correction method

(75) Inventors: Rick Su, Taoyuan (TW); Ying Hao Hsu, Taoyuan (TW)

Correspondence Address: Richard P. Berg, Esq.;c/o LADAS & PARRY, Suite 2100, 5670 Wilshire Boulevard, Los Angeles, CA, 90036-5679, US

(73) Assignee: BENQ CORPORATION

(21) Appl. No.: 10/912,832

(22) Filed: Aug. 5, 2004

(30) Foreign Application Priority Data
Aug. 6, 2003 (TW) 092121545

(51) Int. Cl. G06F 15/00; G03F 3/08

(52) U.S. Cl. 358/1.9; 358/518

(57) ABSTRACT

A parameter correction method corrects the outputting parameters stored in a capturing device. The outputting parameters provide parameters needed while an outputting device outputs the image file. The method is to output the first reference image file as a reference correction picture by the outputting device, perform the white balance method on the capturing device, capture an image from the picture by the capturing device to form a second reference image file comprising a second reference content data, compare the first and second reference content data to obtain the parameter comparison values, input the values to a predetermined procedure to obtain the correction parameters, update the outputting parameters according to the correction parameters, and store the updated parameters in the capturing device. Finally, when there is one image file being formed later, the updated outputting parameters are appended to the headers of the later files.

### BACKGROUND OF THE INVENTION

1. Field of the Invention

The present invention relates to an outputting-image parameter correction method and system for correcting a set of outputting parameters; more particularly, the present invention relates to an outputting-image parameter correction method and system for correcting a set of outputting parameters stored in a digital image capturing device.

2. Description of the Prior Art

With digital pictures becoming more popular, the development of printers that are able to print color pictures become more vigorous. However, even though there are various kinds of color picture printers in the market, the color settings are different in each printer of different brands, and manufacturers of printers are usually different from manufacturers of digital cameras. Thus, color pictures, which are printed by users with printers, often have different colors and brightness in comparison with original digital image files.

Referring to FIG. 1, FIG. 1 is a schematic diagram of the data configuration of a conventional image file 10. The file shown in FIG. 1 is the JPEG format of the digital image format. The JEPG format divides the data area of each image file 10 into the header 12 and the image data area 14. The header 12 is used for storing the image capturing information of a digital image file 10. The image data area 14 is used for storing the image data.

The image capturing information comprises the information recorded in the exchangeable image file format (EXIF). The EXIF is some information added while digital cameras are storing JPEG files; the objective is to record the related information, such as the diaphragm, camera shutter, ISO, date . . . etc., when taking pictures, so as to inform users who want to use the digital image files later.

In order to solve the problems of prior arts, some manufacturers of printers respectively co-operate with manufacturers of digital cameras to establish some sets of correction parameters for providing an outputting device to correct digital image files while outputting them.

In prior arts, the set of correction parameters is stored in the image capturing information of the header 12 of each digital image file, closely following the EXIF. There are two applications of the set of correction parameters of prior arts. The first application is to adjust the set of correction parameters on a user's PC before outputting each digital image file to a printer, and then the printer outputs according to the set of correction parameters, so as to obtain the ideal result in the user's mind. The second application is to pre-store the set of ideal correction parameters of each printer in a digital image capturing device (ex. digital camera) for appending in the header 12 while capturing images every time; therefore, the printers can output the correct digital images later.

However, in the application of the set of correction parameters according to prior arts, the first application must perform the corresponding adjustments by a PC, and then obtain the set of ideal correction parameters. Therefore, the outputting quality of digital images is limited without a PC. Besides, when outputting images, users feel inconvenient for adjusting the set of correction parameters to each digital image file. The problem of the second application is: because the set of correction parameters are predetermined values, digital cameras can not automatically adjust the set of correction parameters according to users' printer types; therefore, the ideal printing status of users' printers is unable to reach.

Therefore, the main objective of the present invention is to provide a parameter correction system and method for solving the problems of different quality between printed pictures and digital image files when printing digital image files.

### SUMMARY OF THE INVENTION

The present invention provides a parameter correction system and method for solving the problems of prior arts.

The present invention provides a parameter correction system and method for correcting a set of outputting parameters, which is being stored in a digital image capturing device for appending to an image file.

The present invention provides a parameter correction system and method; the set of correction parameters corrected by the system is used for providing a plurality of parameters needed while an outputting device is outputting the image file.

The digital image capturing device stores a first reference image file. The first reference image file comprises the set of outputting parameters and a first reference content data. The outputting-image parameter correction method of the present invention is to output the first reference image file to a reference correction picture by the outputting device first; next, perform a white balance procedure to the digital image capturing device under an environment with specific light source; next, capture image from the reference correction picture by the digital image capturing device under the environment with specific light source, so as to form a second reference image file comprising second reference content data; next, compare the first reference content data and the second reference content data to obtain a plurality of parameter comparison values; next, input the parameter comparison values to a predetermined procedure to obtain a plurality of correction parameters and update the set of outputting parameters according to the correction parameters; finally, store the set of updated outputting parameters in the digital image capturing device, and when there is at least one image file being formed later, append the set of updated outputting parameters to the headers of the later image files.

By the present invention, by the operating interface of digital cameras, users can directly pre-adjust users' own digital cameras by the parameter correction method of the present invention, so as to obtain the set of outputting parameters between the digital cameras and printers. When the digital camera captures images later, the set of corrected correction parameters will automatically be appended, that means the set of ideal correction parameters between the digital camera and the printer is in the header of each image file and is used when printing the digital image files. Therefore, the printer corresponded to the digital camera obtains the ideal printing quality of the digital images.

The advantage and spirit of the invention may be understood by the following recitations together with the appended drawings.

### BRIEF DESCRIPTION OF THE APPENDED DRAWINGS

FIG. 1 is a schematic diagram of the data configuration of a conventional image file.

FIG. 2 is a schematic diagram of the reference correction picture according to the embodiment of the present invention.

FIG. 3 is a schematic diagram when the digital image capturing device of the present invention performs the white balance procedure.

FIG. 4 is a schematic diagram when the digital image capturing device of the present invention forms the second reference image file.

FIG. 5 is a schematic diagram of the digital image capturing device applying the parameter correction system of the present invention.

FIG. 6 is a flow chart of the parameter correction method according to the present invention.

### DETAILED DESCRIPTION OF THE INVENTION

The present invention relates to a parameter correction system applied in an image capturing device for correcting a set of outputting parameters. The set of outputting parameters is stored in a digital image capturing device for appending to an image file. The digital image capturing device stores a first reference image file; the first reference image file comprises the set of outputting parameters and a first reference content data. The first reference image file is outputted as a reference correction picture by the outputting device.

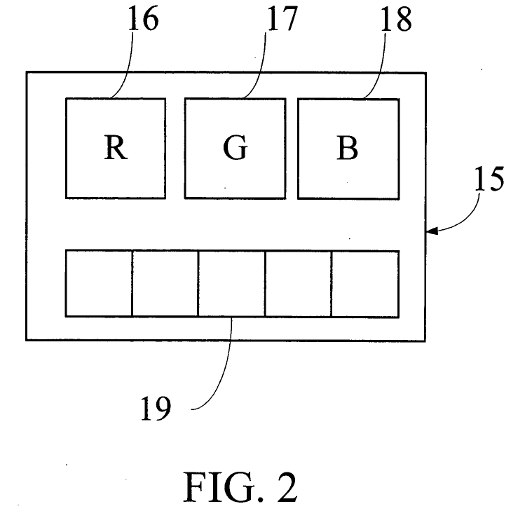

Referring to FIG. 2, FIG. 2 is a schematic diagram of the reference correction picture 15 according to the embodiment of the present invention. The reference correction picture 15 is used for outputting the first reference content data comprising a red area 16, a green area 17, a blue area 18, and a gray level area19. The present invention uses the digital image capturing device to capture image from the reference correction picture 15, so as to form a second reference image file comprising a second reference content data. The present invention further compares the first reference content data and the second reference content data to obtain a plurality of parameter comparison values, and a plurality of correction parameters are also obtained through a predetermined procedure according to the parameter comparison values.

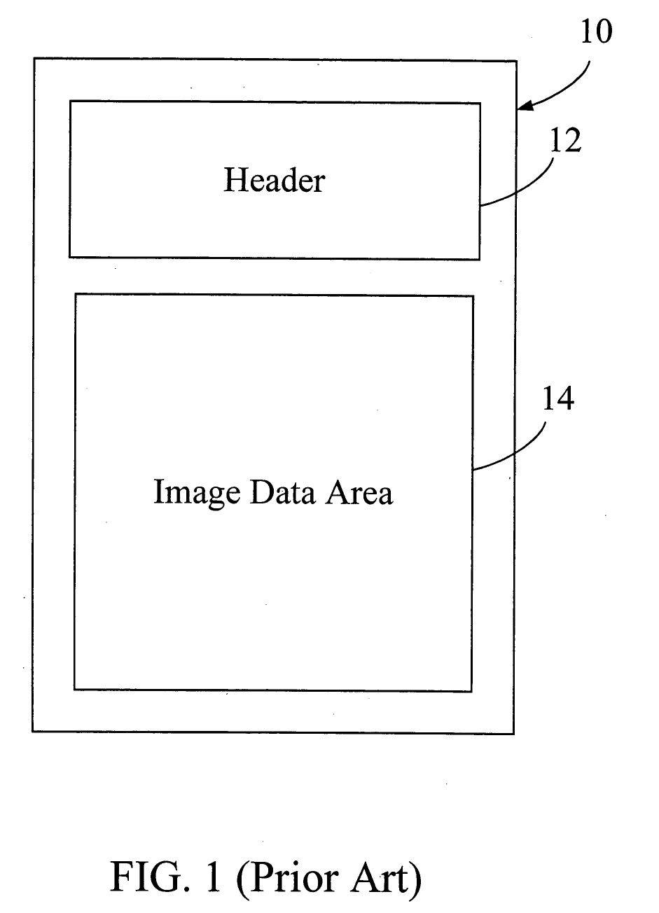

The correction parameters are used for updating the set of outputting parameters needed while an outputting device (ex. color printers) outputs the image file. As shown in FIG. 1, the image file 10 comprises a header 12 for storing the set of outputting parameters, which is used when the outputting device outputs the image file later.

Before the present invention enters the parameter correction step, a white balance procedure must precede. The convention white balance procedure is a procedure for digital cameras to correct the basic colors of digital cameras under environments with different brightness of lighting. The main objective is to correct the brightness of the environment. By measuring the color temperature and brightness of an environment with a specific light source and obtaining the corresponding parameters, the parameters related to the light source are further consulted while proceeding the parameter correction step, thus ensuring that the outputting parameters of the present invention do not change with the effect of the lighting brightness of an environment.

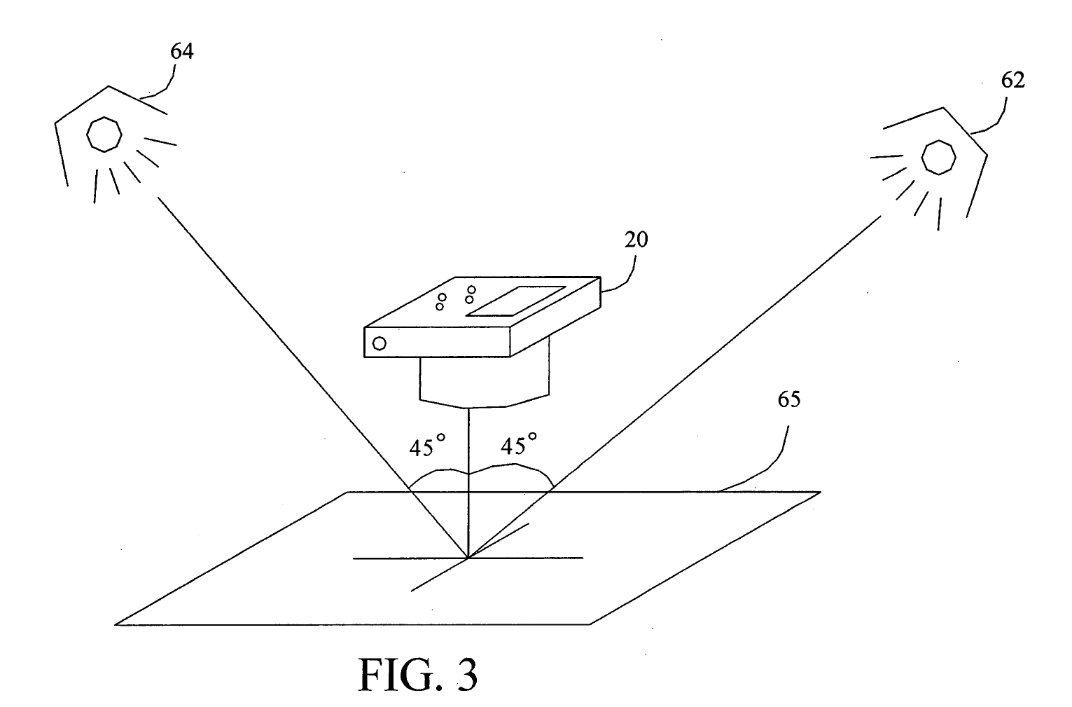

Referring to FIG. 3, FIG. 3 is a schematic diagram when the digital image capturing device 20 of the present invention performs the white balance procedure. The digital image capturing device 20 captures images of a plain paper from a vertical angle under an environment with specific light source; this environment uses two incandescent light sources 62 and 64, placed in opposite direction, to illuminate the plain paper in an angle of 45 degree from the horizontal plane, thus correcting the brightness of the environment and obtaining the corresponding parameters related to the color temperature and brightness of the environment with the specific light source. The parameters are used as the reference in later steps of the present invention.

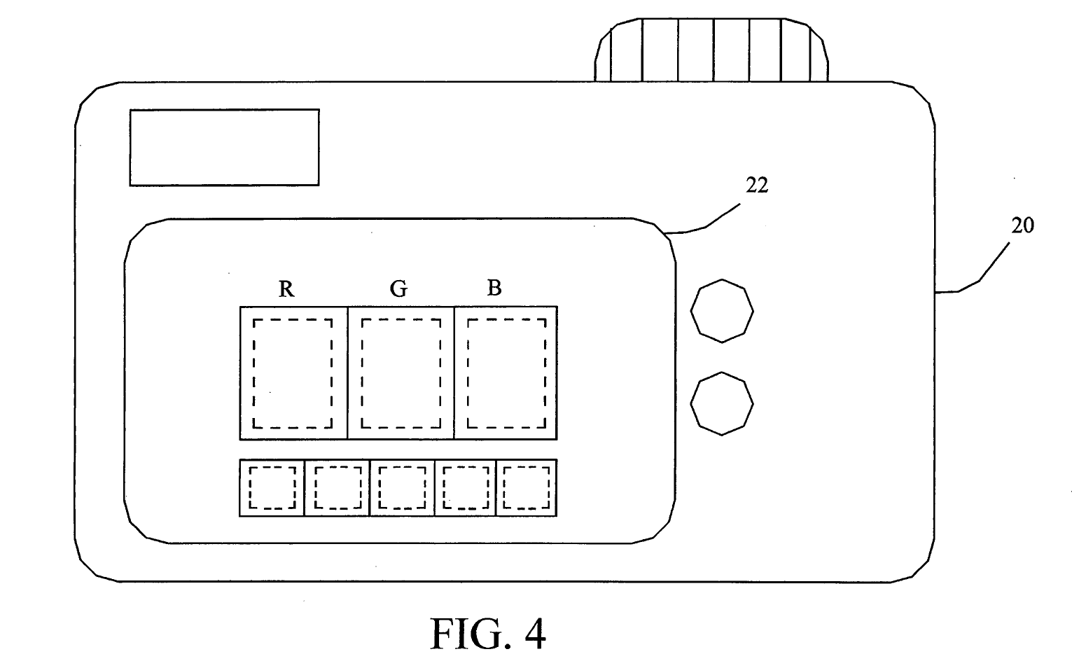

Referring to FIG. 4, FIG. 4 is a schematic diagram when the digital image capturing device 20 of the present invention forms the second reference image file 25. After performing the white balance procedure shown in FIG. 3, the second reference image file 25 is formed in the digital image capturing device 20. FIG. 4 shows the image displayed on the LCD screen 22 when the digital image capturing device 20 captures images. Under the environment with the specific light source, the reference correction picture 15 is put in the place where the original plain paper is located, and at this time, the first reference content data is displayed on the LCD screen 22 first. The red, green, and blue areas are expressed in solid lines shown in FIG. 4. Then, an image is captured from the reference correction picture 15 by the digital image capturing device 20, so the image of the reference correction picture 15 is displayed on the LCD screen 22 at the same time. The frame lines of the red, green, and blue areas are expressed in dotted lines shown in FIG. 4. When the first reference content data and the reference correction picture 15 displayed on the LCD screen 22 are fully overlapping, that also means the solid lines and the dotted lines shown in FIG. 4 are overlapping; the shutter is then pressed to capture the second reference image file 25 to obtain the second reference content data. By this way, the digital image capturing device 20 can compare the first reference content data and the second reference content data and indicate the difference between the image file of the outputting picture of the outputting device and the digital image capturing device 20 under the condition of the environment with the same light source.

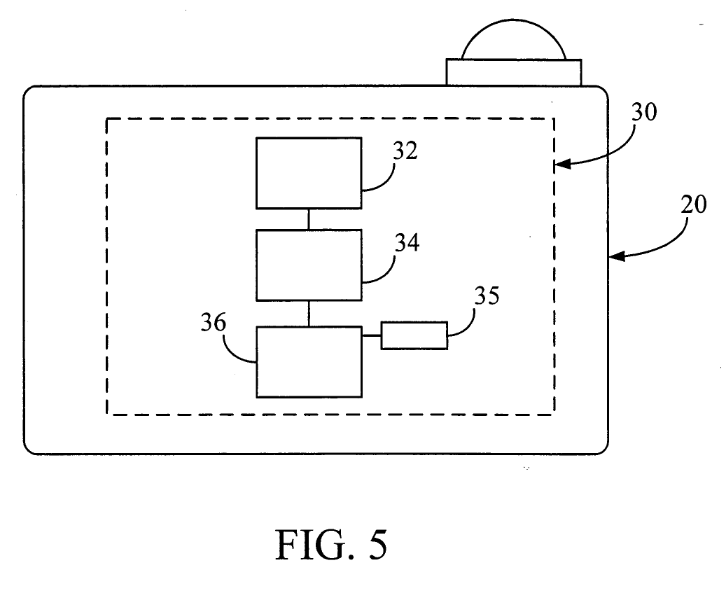

Referring to FIG. 5, FIG. 5 is a schematic diagram of the digital image capturing device 20 applied the parameter correction system 30 of the present invention. The parameter correction system comprises a memory 32, an image capturing module 34, a parameter correction comparison table 35, and a correction module 36. The memory 32 is used for storing the set of outputting parameters. The image capturing module 34 is used for performing the white balance procedure on the digital image capturing device and capturing the image from the reference correction picture 15 under the environment with specific light source, so as to form a second reference image file.

The correction module 36 is used for comparing the first reference content data and the second reference content data to obtain the parameter comparison values and inputting the parameter comparison values to a predetermined procedure to obtain a plurality of correction parameters. The correction module 36 further updates the set of outputting parameters according to the correction parameters and stores the set of updated outputting parameters in the digital image capturing device 20. The predetermined procedure is to consult the parameter correction comparison table 35 with the parameter comparison values and obtain the corresponding correction parameters.

The parameter correction comparison table 35 comprises various kinds of correction parameters, such as the correction parameters for the colors and brightness of the red, green, and blue color, and the correction parameters for the gray level expression of each color.

According to the method to promote the set of correction parameters by conventional printer manufacturers, they provide the comparison formulae of the correction parameters and the outputting parameters of printers for actual printing to the manufacturers of digital cameras. Therefore, the digital cameras can adjust and obtain a suitable outputting reference image between the digital camera and the printer by the correction parameters and the comparison formulae. When digital cameras output the later image files, the data of the image files related to the outputting reference pictures outputs correspondingly, so as to obtain the best quality when the printer prints color pictures.

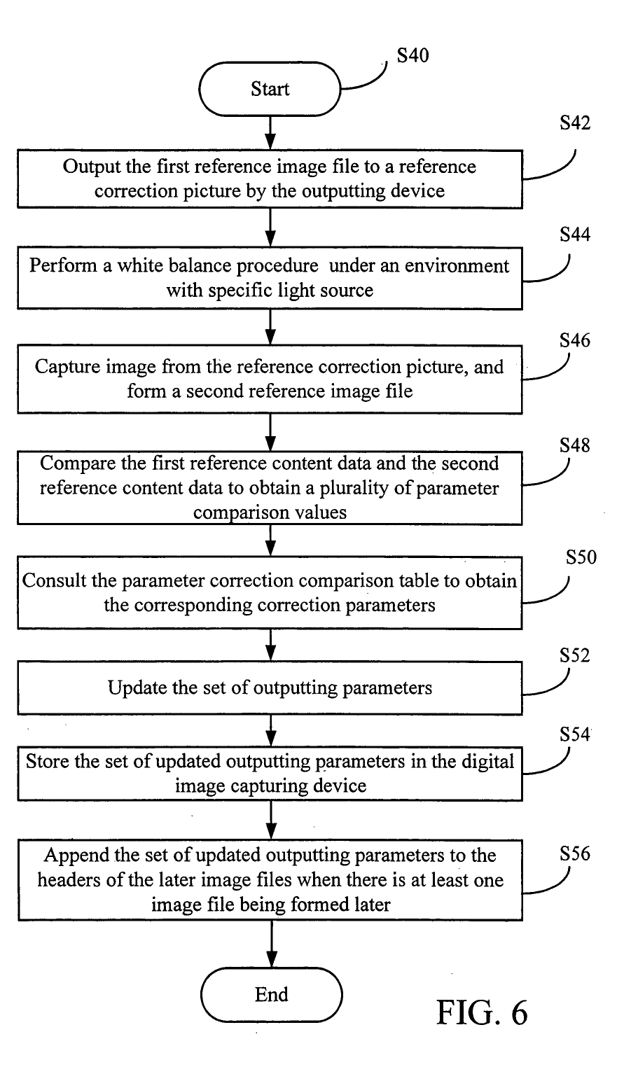

Referring to FIG. 6, FIG. 6 is a flow chart of the parameter correction method according to the present invention. The method of the present invention comprises the following steps:
Step S40: Start;
Step S42: Output the first reference image file as a reference correction picture by the outputting device;
Step S44: Perform the white balance procedure on the digital image capturing device 20 under an environment with specific light source;
Step S46: Capture an image from the reference correction picture 15 under the environment with specific light source, so as to form a second reference image file;
Step S48: Compare the first reference content data and the second reference content data to obtain a plurality of parameter comparison values;
Step S50: Consult the parameter correction comparison table with the parameter comparison values to obtain the corresponding correction parameters;
Step S52: Update the set of outputting parameters according to the correction parameters;
Step S54: Store the set of updated outputting parameters in the digital image capturing device 20;
Step S56: When there is at least one image file being formed later, append the set of updated outputting parameters to the headers 12 of the later image files;
Step S58: End.

By the present invention, through the operating interface of digital cameras, users can directly pre-adjust their own digital cameras by the parameter correction method of the present invention, so as to obtain the set of outputting parameters between the digital cameras and printers. When the digital camera captures images later, the set of corrected correction parameters is automatically appended, that means the set of ideal correction parameters between the digital camera and the printer is in the header of each image file and is used when printing the digital image files. Therefore, the printer corresponding to the digital camera obtains the ideal printing quality of the digital images.

Comparing with prior arts, the outputting-image parameter correction method of the present invention is to output the first reference image file as a reference correction picture by the outputting device first; next, then, a white balance procedure is performed on the digital image capturing device under an environment with specific light source; next, an image is captured from the reference correction picture by the digital image capturing device under the environment with specific light source, so as to form a second reference image file that comprises a second reference content data; after that, the first reference content data is compared with the second reference content data to obtain a plurality of parameter comparison values; furthermore, the parameter comparison values are inputted into a predetermined procedure to obtain a plurality of correction parameters, and the set of outputting parameters are updated according to the correction parameters; finally, the set of updated outputting parameters are stored in the digital image capturing device, and when there is at least one image file being formed later, the set of updated outputting parameters is appended to the headers of the later image files.

By the present invention, users of digital cameras and printers no longer need to adjust the printing quality through their personal computers when printers print image files, making it possible to obtain the best printing quality by directly connecting printers with digital cameras. Besides, the present invention uses the correction system and method internally in digital cameras, further breaking the usual limitation that the manufacturers of the printers and digital cameras are different; therefore, the present invention obtains the best outputting parameters of digital cameras to each printer and optimizes the efficiency of each printer.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. An outputting-image parameter correction method for correcting a set of outputting parameters, which being stored in a digital image capturing device for appending to an image file, the set of outputting parameters providing a plurality of parameters while an outputting device outputting the image file needed, the image file comprising a header for storing the set of outputting parameters, and an image data area for storing an image content data, the digital image capturing device storing a first reference image file, the first reference image file comprising the set of outputting parameters and a first reference content data, the outputting-image parameter correction method comprising the following steps:
outputting the first reference image file as a reference correction picture by the outputting device;
performing a white balance procedure to the digital image capturing device under an environment with specific light source;
capturing image from the reference correction picture by the digital image capturing device under the environment with specific light source, so as to form a second reference image file comprising a second reference content data;
comparing the first reference content data and the second reference content data to obtain a plurality of parameter comparison values;
inputting the parameter comparison values to a predetermined procedure to obtain a plurality of correction parameters;
updating the set of outputting parameters according to the correction parameters; and
storing the set of updated outputting parameters in the digital image capturing device, and when there is at least one image file being formed later, appending the set of updated outputting parameters to the headers of the later image files.

2. The outputting-image parameter correction method of claim 1, wherein the digital image capturing device stores a parameter correction comparison table, and wherein the predetermined procedure is to consult the parameter correction comparison table with the parameter comparison values, so as to obtain the corresponding correction parameters.

3. The outputting-image parameter correction method of claim 1, wherein the white balance procedure is to correct the brightness by using the digital image capturing device to vertically capture images of a plain paper under the environment with specific light source.

4. The outputting-image parameter correction method of claim 3, wherein the environment with specific light source means to use two incandescent light sources in opposite direction to illuminate the plain paper in an angle of 45 degree from the horizontal plane.

5. The outputting-image parameter correction method of claim 1, wherein the first reference content data comprises a red area, a green area, and a blue area.

6. The outputting-image parameter correction method of claim 5, wherein the parameter comparison values are generated by comparing the red area, the green area, and the blue area of the first reference content data and the second reference content data.

7. The outputting-image parameter correction method of claim 5, wherein the first content data further comprises at least one gray level area.

8. The outputting-image parameter correction method of claim 7, wherein the parameter comparison values are generated by comparing the red area, the green area, the blue area, and the gray level area of the first reference content data and the second reference content data.

9. A parameter correction system applying in an image capturing device for correcting a set of outputting parameters, which being stored in a digital image capturing device for appending to an image file, the set of outputting parameters providing a plurality of parameters, the image file comprising a header for storing the set of outputting parameters, and an image data area for storing an image content data, the digital image capturing device storing a first reference image file, the first reference image file comprising the set of outputting parameters and a first reference content data, and being outputted to a reference correction picture by the outputting device, the parameter correction system comprising:
a memory for storing the set of outputting parameters;
an image capturing module for
performing a white balance procedure to the digital image capturing device under an environment with specific light source; and
capturing image from the reference correction picture by the digital image capturing device under the environment with specific light source, so as to form a second reference image file comprising a second reference content data; and
a correction module for
comparing the first reference content data and the second reference content data to obtain a plurality of parameter comparison values;
inputting the parameter comparison values to a predetermined procedure to obtain a plurality of correction parameters;
updating the set of outputting parameters according to the correction parameters; and
storing the set of updated outputting parameters in the digital image capturing device, and when there is at least one later image file being formed, appending the set of updated outputting parameters to the headers of the later image files.

10. The parameter correction system of claim 9, further comprising a parameter correction comparison table, and wherein the predetermined procedure consults the parameter correction comparison table with the parameter comparison values, so as to obtain the corresponding correction parameters.

11. The parameter correction system of claim 9, wherein the white balance procedure is to correct the brightness by using the digital image capturing device to vertically capture images of a plain paper under the environment with specific light source.

12. The parameter correction system of claim 11, wherein the environment with specific light source means to use two incandescent light sources in opposite direction to illuminate the plain paper in an angle of 45 degree from the horizontal plane.

13. The parameter correction system of claim 9, wherein the first reference content data comprises a red area, a green area, and a blue area.

14. The parameter correction system of claim 13, wherein the parameter comparison values are generated by comparing the red area, the green area, and the blue area of the first reference content data and the second reference content data.

15. The parameter correction system of claim 13, wherein the first content data further comprises at least one gray level area.

16. The parameter correction system of claim 15, wherein the parameter comparison values are generated by comparing the red area, the green area, the blue area, and the gray level area of the first reference content data and the second reference content data.
